(19) United States
(12) Patent Application Publication
(10) Pub. No.: US 2003/0006377 A1
(43) Pub. Date: Jan. 9, 2003

(54) Tandem acceleration electrostatic lens

(76) Inventor: Setsuo Nomura, Nishitama-gun (JP)

Correspondence Address: KENYON & KENYON, 1500 K STREET, N.W., SUITE 700, WASHINGTON, DC, 20005, US

(21) Appl. No.: 10/242,760

(22) Filed: Sep. 13, 2002

Related U.S. Application Data
(63) Continuation of application No. 09/305,772, filed on May 5, 1999.

(30) Foreign Application Priority Data
May 14, 1998 (JP) 10-131717

(51) Int. Cl. H01J 37/12

(52) U.S. Cl. 250/396 R

(57) ABSTRACT

A structure of aligning acceleration mode convergence electrostatic lenses is employed. One acceleration mode convergence electrostatic lens is formed in a range of the first, the second and the third electrodes, and the other acceleration mode convergence electrostatic lens is formed in a range of the third, the fourth and the fifth electrodes. Since energy of an ion beam passing through a position where convex lens action is produced is large, it is possible to maintain the characteristic that the chromatic aberration coefficient of the acceleration electrostatic lens is small. By increasing number of positions performing convex lens action, it is possible to obtain the acceleration mode convergence with a low lens voltage.

### BACKGROUND OF THE INVENTION

The present invention relates to an electrostatic lens for controlling convergence of a charged particle beam, and particularly to an electrostatic lens small in aberration and capable of being operated with a low voltage.

In recent years, a technology of performing micromachining of a sample by irradiating a finely converged high-energy charged particle beam, particularly an ion beam on the sample. The finer the ion beam becomes, the finer the machining can be performed. An electrostatic lens is used for controlling convergence of the ion beam. The electrostatic lens (hereinafter, referred to as an objective lens) forming the fine beam on the sample is arranged opposite to the irradiated sample, and generally composed of three electrodes. The ion beam can be finely converged by applying a positive polar or a negative polar voltage to the central electrode.

The convergence method of converging an ion beam having positive charge to a converged ion beam by applying a positive polar voltage to the central electrode of the electrostatic lens is called a deceleration mode convergence method, and the convergence method of converging the ion beam to a converged ion beam by applying a negative polar voltage to the central electrode is called an acceleration mode convergence method. A necessary condition to finely converge the ion beam is that a lens having small aberration is used under a condition of a short focal length. The deceleration mode convergence method can converge an ion beam with a short focal length by a very low applied voltage compared to the acceleration mode convergence method. On the other hand, the acceleration mode convergence method can converge an ion beam with a very small aberration compared to the deceleration mode convergence method.

A problem of the acceleration mode convergence method is that a very high voltage is required when a high energy ion beam is tried to be converged with a short focal length. For instance, when an ion beam of 30 keV generally used in micromachining is tried to be converged on a sample 7 mm apart from the lens, it is required to apply a high voltage as high as −82.1 kV to the central electrode.

### SUMMARY OF THE INVENTION

A first object of the present invention is to provide an electrostatic lens which can converge a high energy charged particle beam with a very low voltage compared to that in the acceleration mode convergence method, and can form a converged ion beam having a very small aberration compared to that in the deceleration mode convergence method.

In order to attain the above-mentioned object, in the tandem electrostatic lens of the present invention, lens action is performed by an electrode arrangement having a plurality of electrostatic lenses converging a charged particle beam by the acceleration mode convergence method arranged in series. That is, by making use of the small aberration characteristic of the acceleration mode convergence method, the problem of the small converging effect of charged particle beam is solved by arranging a plurality of lenses in series.

The present invention is characterized by an electrostatic lens comprising a function of converging a charged particle beam, wherein the electrostatic lens has an electrode arrangement of aligning a plurality of electrostatic lenses performing lens action by an acceleration mode convergence method.

The present invention is characterized by an electrostatic lens comprising at least five electrodes, wherein when the entrance electrode arranged in an entrance side of a charged particle beam is counted as the first electrode, the electrodes arranged in the even-number-th positions counted from the first electrode are applied with a voltage potential higher than a voltage potential applied to the entrance electrode. Therein, the even-number-th electrodes can be supplied with the voltage from an electric power source.

The present invention is characterized by an electrostatic lens comprising at least five electrodes, wherein the electrodes arranged in the odd-number-th positions counted from the entrance electrode arranged in an entrance side of a charged particle beam are applied with a voltage potential lower than a voltage potential applied to the entrance electrode, and the electrodes arranged in the even-number-th positions are applied with a voltage potential higher than the voltage potential applied to the entrance electrode. Therein, the odd-number-th electrodes can be supplied with the voltage by deviling a voltage of an electric power source for accelerating a charged particle beam.

Further, the present invention is characterized by a charged particle beam irradiation apparatus converging a charged particle beam using an objective lens to irradiate the charged particle beam on a sample, wherein the objective lens is any one of the above-mentioned electrostatic lenses of the present invention an image plane of which corresponds to a surface of the charged particle irradiated sample.

Furthermore, the present invention is characterized by a charged particle beam image projection apparatus which reductively projects a charged particle beam passed through a charged particle beam image projection stencil on a sample using an objective lens, wherein the objective lens is any one of the above-mentioned electrostatic lenses of the present invention an object plane of which corresponds to the stencil.

Since the tandem acceleration electrostatic lens in accordance with the present invention has the electrode arrangement of arranging the plurality of electrostatic lenses performing the lens action with acceleration convergence mode method (hereinafter, referred to as the conventional acceleration convergence lenses), it is possible to maintain the characteristic that the chromatic aberration coefficient of the acceleration electrostatic lens is small. Number of positions performing convex lens action is increased compared to that of the conventional acceleration convergence lens. Since the convergence action is performed by many times of the convex action, it is possible to obtain the same effect of the convergence action by a lens voltage lower than that of the conventional acceleration convergence lens.

### BRIEF DESCRIPTION OF DRAWINGS

FIG. 1 is a schematic view showing an embodiment of an electrostatic lens in accordance with the present invention.

FIG. 2 is an explanatory graph showing an ion beam convergence method by a conventional acceleration mode convergence lens.

FIG. 3 is an explanatory graph showing an ion beam convergence method by a tandem acceleration electrostatic lens in accordance with the present invention.

FIG. 4 is a schematic view showing an example of an ion beam machining apparatus to which a tandem acceleration electrostatic lens in accordance with the present invention is applied.

FIG. 5 is a schematic view showing an example of an ion beam image projection apparatus to which a tandem acceleration electrostatic lens in accordance with the present invention is applied.

### DESCRIPTION OF THE PREFERRED EMBODIMENTS

An embodiment of the present invention will be described below, referring to the accompanied drawings. Designated values for voltage, focal distance and so on to be used in the following description are examples simply for the sake of understanding, and the present invention is not limited by the designated values.

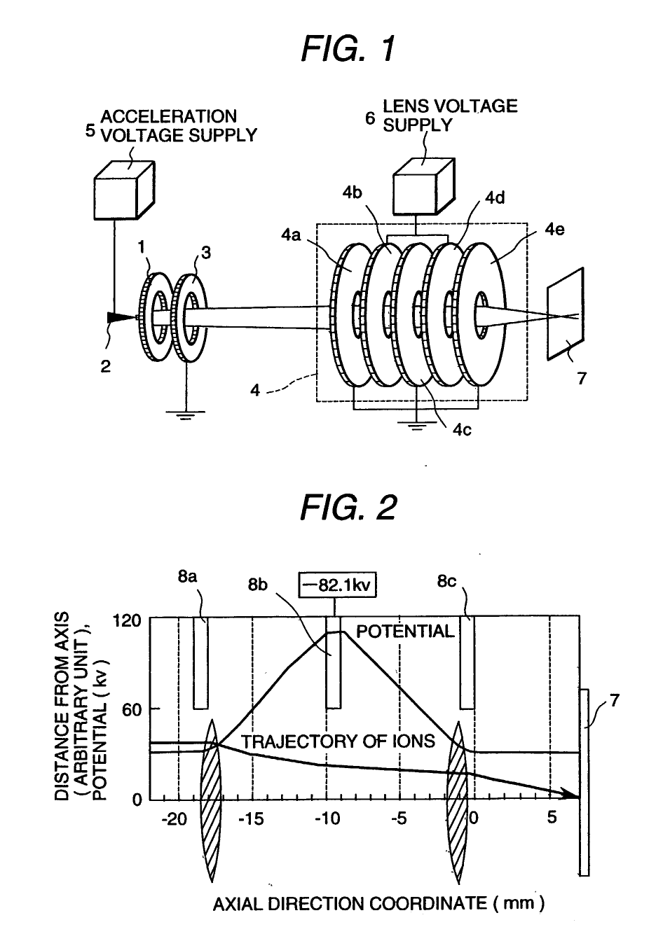

FIG. 1 is a schematic view showing an embodiment of an electrostatic lens in accordance with the present invention. An electrostatic lens (an objective lens) 4 in this embodiment comprises five electrodes each of which has a hole for letting an ion beam pass through in the center. Ga⁺ ions extracted from an ion source 2 by applying a high voltage to an extraction electrode 1 are accelerated by a grounded acceleration electrode 3 so as to have an energy of 30 keV to enter an objective lens 4. The energy of 30 keV is supplied by an acceleration voltage supply 5. The objective lens 4 is composed of five electrodes 4a to 4e. When the electrodes are counted as the first, the second, the third, the fourth and the fifth electrodes in order of arranged position from the incident side of the ions, a lens voltage of −29.5 kV is applied to the second electrode 4b and the fourth electrode 4d from a lens voltage supply 6.

Since each of the first electrode 4a, the third electrode 4c and the fifth electrode 4e is kept to zero voltage similarly to a sample 7, one acceleration mode convergence electrostatic lens is formed in the range of the first, the second and the third electrodes 4a to 4c, and the other acceleration mode convergence electrostatic lens is formed in the range of the third, the fourth and the fifth electrodes 4c to 4e. The ion beam coming out from the objective lens 4 becomes a fine beam and irradiates the sample 7 placed at a position 7 mm apart from the objective lens 4 (hereinafter, this distance is referred to as a working distance W). Energy of the ion beam is not decreased in the objective lens from the energy which the ion beam has at entering into the objective lens.

In the example shown in FIG. 1, the tandem acceleration electrostatic lens is constructed by arranging the five disc-shaped electrodes 4a to 4e having a hole diameter of 2 mm and a plate thickness of 1 mm with a 3 mm spacing between the electrodes. As a result, the beam is converged onto the sample 7 having the 7 mm working distance with a −29.5 kV lens voltage which is nearly equal to the acceleration voltage of 30 kV. When an ion beam of 30 keV is converged onto the sample having a working distance of 7 mm using the conventional acceleration mode convergence electrostatic lens, it is necessary to apply a high voltage as high as 82.1 kV to the lens.

From the viewpoint of manufacturing an apparatus, it is very uneconomical and highly costly to prepare a high voltage nearly three times as high as the acceleration voltage of 30 kV to supply it to the ion beam irradiation apparatus. Further, stably applying the high voltage as high as −82.1 kV to the electrodes is technically very difficult compared to stably applying the voltage of approximately 30 kV, which is also a problem equivalent to the above economical problem in one aspect. The present invention aims at solving these problems on manufacturing the apparatus and satisfying the industrial requirement of need for high energy fine beams.

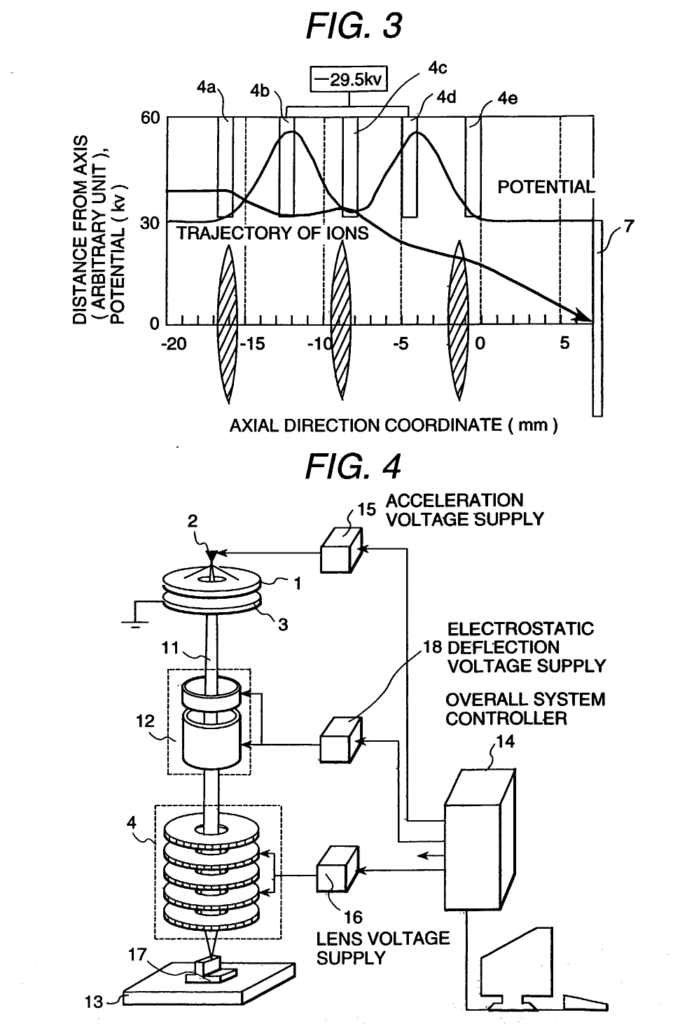

As described above, in the present invention, the disadvantage of the weak convergence force in the acceleration mode convergence method is covered by using the plurality of aligned acceleration mode convergence electrostatic lenses to increase the positions for performing lens action. Referring to FIG. 2 and FIG. 3, description will be made below on the principle that using of the plurality of aligned acceleration mode convergence electrostatic lenses can converge the charged particle ion beam without losing characteristics of the small aberration of the acceleration lens action and with a low voltage.

Calculation has been performed using a computer on states that an trajectry of ions in the lens is deflected toward the lens axis by the convergence action. FIG. 2 and FIG. 3 show comparison between the trajectries in the conventional acceleration electrostatic lens and in the tandem acceleration electrostatic lens in accordance with the present invention. FIG. 2 shows the convergence action of the conventional one-stage acceleration mode convergence electrostatic lens composed of three electrodes 8a, 8b and 8c, and FIG. 3 shows the convergence action of the two-stage tandem acceleration convergence electrostatic lens in accordance with the present invention having the five electrodes 4a to 4e. The rectangles in the figures indicate positions of the electrodes and the sample. The convex lens action is generated at positions where the trajectry of ions are deflected toward the axis of lens. In the figures, the positions are shown by optical convex lens marks.

Further, in FIG. 2 and FIG. 3, electrostatic potential at each position inside the lens is also shown. Since the potential is expressed by taking the potential of the ion source as the reference, the potential expresses the kinetic energy of the ions at each position. That is, in the present specification, the “potential” is defined as that shown in FIG. 2 or FIG. 3.

As shown in FIG. 2, when a voltage of −82.1 kV (30+82.1=112.1 kV in the unit of potential) is applied to the central electrode 8b in the conventional electrostatic lens, the convex lens action is produced at positions near the first electrode 8a and the third electrode 8c to converge the ion beam so that the ion beam and the lens axis intersect at the position of the sample 7. The convex lens action is produced at a position where the potential curve has a convex shape toward the lower value side. Therefore, in the lens of FIG. 2, the convex lens action is produced at two positions near the first electrode 8a and near the third electrode 8c.

On the other hand, in the tandem acceleration electrostatic lens in accordance with the present invention, the convex lens action is produced at three positions near the first electrode 4a, the third electrode 4c and the fifth electrode 4e to converge the ion beam as shown in FIG. 3. This is because the potential distribution on the electrostatic lens axis has convex shapes toward the lower value side at the three positions. Since number of the positions having the convex lens action is 1.5 times as many as that in the lens of FIG. 2, the beam can be converged at the same position as the position in FIG. 2 by the low lens voltage (−29.5 kV). In other words, although the conventional acceleration lens shown in FIG. 2 requires the lens voltage of −82.1 kV, the tandem electrostatic lens in accordance with the present invention shown in FIG. 3 can focus the ion beam having an energy of 30 keV on to the sample 7 at the position apart from the lens by the same distance with the lens voltage of −29.5 kV.

In addition, since the potential at the three position where the tandem acceleration lens shown in FIG. 3 performs the convex lens action is approximately 30 kV which is nearly the same as the potential of the convex lens portion of FIG. 2, the characteristic of the small chromatic aberration of the acceleration electrostatic lens of FIG. 2 is maintained. The reason why the chromatic aberration of the acceleration electrostatic lens is smaller than that of the deceleration electrostatic lens is that kinetic energy of ions at the position of the lens action is higher than that in the deceleration electrostatic lens. That is, effect of energy deviation of ions on the ion trajectry is small when the kinetic energy is high. When the magnitude of chromatic aberration is compared on the basis of chromatic aberration coefficient (hereinafter, referred to as Cc), the Cc of the lens of FIG. 2 is 18 mm. On the other hand, the Cc of the lens of FIG. 3 is 21 mm.

FIG. 4 is a schematic view showing an example of a converged ion beam machining apparatus for working a sample with a fine ion beam to which a tandem acceleration electrostatic lens in accordance with the present invention is applied. The tandem acceleration electrostatic lens is used as an objective lens of the converged ion beam machining apparatus.

An ion beam 11 emitted from an ion source 2 connected to an acceleration voltage supply 15 enters into an electrostatic deflector 12, and then enters into the objective lens 4 formed of the tandem acceleration electrostatic lens in accordance with the present invention. The ion beam 11 converged by the objective lens 4 supplied with voltage from a lens voltage supply 16 is irradiated on a sample 17 mounted on a sample stage 13. The irradiation position on the sample 17 can be arbitrarily selected by controlling an output voltage of an electrostatic deflector voltage supply 18 according to a command from an overall system controller 14. The overall system controller 14 contains a program for performing ion working to slice a block of sample into thin wall-shaped samples, and FIG. 4 shows a feature under forming the thin wall-shaped samples.

How fine working can be performed, that is, the accuracy of the working is determined by the spot size of the irradiated ion beam. In a conventional ion beam machining apparatus, a conventional three-electrode electrostatic lens is employed as the objective lens, and used under conditions of placing a sample at a position of a working distance W of 23 mm, a focal length f of the objective lens of 25 mm and a lens voltage of −29.5 kV. An ion beam having a current value of 50 pA and a spot size (beam diameter) of 19 nm produced by the objective lens is used for the ion beam working.

In the ion beam machining apparatus of FIG. 4 in accordance with the present invention, the ion beam can be converged with a focal length of 16 mm (a working distance W is 7 mm) even under a condition of a lens voltage of −24.5 kV. In general, a chromatic aberration coefficient of a lens becomes small when the focal length is small. As the result of shortening the focal length to approximately 60%, an ion beam having a spot size of 14 nm and a current value of 50 pA can be used. That is, the working accuracy of minute working is improved by (19−14)/19=26% compared to that in the case of using the conventional lens.

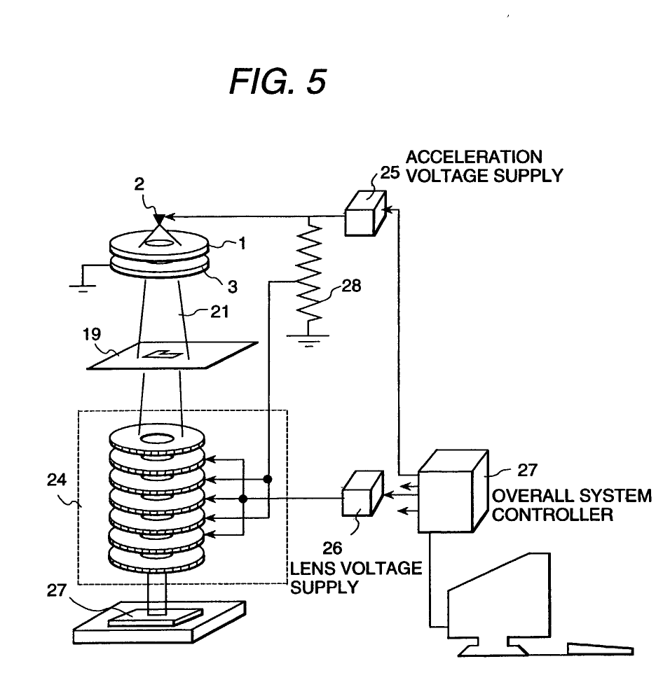

FIG. 5 is a schematic view showing an example of an ion beam image projection apparatus to which a tandem acceleration electrostatic lens in accordance with the present invention is applied. An ion beam 21 emitted from an ion source 2 connected to an acceleration voltage supply 25 and accelerated to 30 keV is irradiated on a stencil 19 made of molybdenum having an L-shaped hole in the center. The ion beam passed through the hole of the stencil 19 is affected with lens action by an objective lens 24 formed of the tandem acceleration electrostatic lens to be projected onto a sample 27. An ion irradiated portion is scraped and an L-shaped depressed portion is worked and formed on the sample 27.

The objective lens 24 is composed of seven electrodes, and a voltage of approximately −12 kV is applied to the second, the fourth and the sixth electrodes counting from the ion incident side from a lens voltage supply 26 under control of an overall system controller 27. Further, a voltage of +11 kV is applied to the third and the fifth electrodes. Number of convex lens action portions is increased by one compared to in the case of the tandem acceleration electrostatic lens composed of the five electrodes, and the lens action capable of focusing on a position of 7 mm working distance W with the lower lens voltages of −12 kV and +11 kV by the degree of increased number of convex lens action portions.

Therein, the positive polar voltage (+11 kV) supplied to the lens of FIG. 5 is supplied by dividing a voltage produced by an acceleration voltage supply 25 using a resistor 28. Therefore, in the lens, there is no need to prepare an additional power source for generating the positive polar voltage.

According to the present invention, the electrostatic lens of a short focal length and acceleration mode convergence can be realized by applying a low lens voltage. As a result, for example, to the ion beam having an ion beam energy of −30 keV and a current value of 50 pA, it is possible to reduce the ion beam spot size by 26% compared to that in the conventional lens.

What is claimed is:

1. An ion beam apparatus comprising an ion source for generating a positive ion beam and an electrostatic objective lens focusing the positive ion beam on a sample, the electrostatic lens comprising at least five electrodes, with an exit electrode arranged on an exit side of the positive ion beam defined as a first electrode, a second electrode and a fourth electrode from the first electrode are each supplied with a negative voltage so that the second and fourth electrodes are higher in potential than the first electrode.

2. An ion beam apparatus according to claim 1, wherein said apparatus reductively projects a charged particle beam passed through a charged particle beam image projection stencil on a sample using said objective lens, the object plane of said objective lens corresponding to said stencil.

3. An ion beam apparatus according to claim 1, wherein the image plane of said objective lens corresponds to a surface of the charged particle irradiated sample.

4. An ion beam apparatus according to claim 1, wherein said second and fourth electrodes are supplied with voltage from a single electric power source.

5. An ion beam apparatus according to claim 4, wherein the image plane of said objective lens corresponds to a surface of the charged particle irradiated sample.

6. An ion beam apparatus according to claim 4, wherein said apparatus reductively projects a charged particle beam passed through a charged particle beam image projection stencil on a sample using said objective lens, the object plane of said objective lens corresponding to said stencil.

7. An ion beam apparatus according to claim 1, comprising five intermediary electrodes arranged between an entrance electrode and an exit electrode through which said positive ion beam passes, wherein odd-numbered ones of the five intermediary electrodes, as counted from exit electrode are each supplied with a voltage at a level such that the odd-numbered electrodes are lower in potential than the entrance electrode and the exit electrode, and even-numbered ones of the five intermediary electrodes are each supplied with a voltage at a level such that the even-numbered electrodes are higher in potential than the entrance electrode and the exit electrode.

8. An ion beam apparatus according to claim 7, wherein said odd-numbered electrodes are supplied with voltage obtained by dividing a voltage of an electric power source for accelerating the charged particle beam.

9. An ion beam apparatus according to claim 7, wherein the image plane of said objective lens corresponds to a surface of the charged particle irradiated sample.

10. An ion beam apparatus according to claim 7, wherein said apparatus reductively projects a charged particle beam passed through a charged particle beam image projection stencil on a sample using said objective lens, the object plane of said objective lens corresponding to said stencil.

11. An ion beam apparatus according to claim 7, wherein said odd-numbered electrodes are supplied with voltage obtained by dividing a voltage of an electric power source for accelerating the charged particle beam.
